(19) United States
(12) Patent Application Publication
(10) Pub. No.: US 2023/0175129 A1
(43) Pub. Date: Jun. 8, 2023

(54) METHODS FOR IMPROVING THIN FILM QUALITY

(71) Applicant: ASM IP Holding B.V., Almere (NL)

(72) Inventors: Jereld Lee Winkler, Gilbert, AZ (US); Petri Raisanen, Gilbert, AZ (US); Po-Yi Su, Tempe, AZ (US)

(21) Appl. No.: 18/072,764

(22) Filed: Dec. 1, 2022

Related U.S. Application Data
(60) Provisional application No. 63/264,979, filed on Dec. 6, 2021.

(51) Int. Cl. C23C 16/455; C23C 16/44; C23C 16/34; C23C 16/08

(52) U.S. Cl. CPC C23C 16/45534; C23C 16/4408; C23C 16/34; C23C 16/08

(57) ABSTRACT

Methods for depositing a thin film with improved film qualities on a hydrogen-terminated surface of a substrate are disclosed. The methods may comprise an atomic layer deposition (ALD) process comprising a plurality of deposition cycles comprising contacting the substrate with a first vapor phase metal halide or metalorganic reactant, contacting the substrate with the second vapor phase reactant, and contacting the substrate with a growth inhibitor. A growth inhibitor may be a non-consumable agent that is not incorporated into the deposited film during the deposition process and helps improve the properties of the deposited film. The growth inhibitor may comprise a vapor phase halide, such as HCl, or an organic molecule.

### CROSS-REFERENCE TO RELATED APPLICATIONS

This application is a nonprovisional of, and claims priority to and the benefit of, U.S. Provisional Patent Application No. 63/264,979, filed Dec. 6, 2021 and entitled “METHODS FOR IMPROVING THIN FILM QUALITY,” which is hereby incorporated by reference herein.

### BACKGROUND

### Field

The present disclosure relates generally to the field of semiconductor device manufacturing and, more particularly, to processes and methods for improving the qualities of thin films deposited by a vapor deposition process.

### Description of the Related Art

There is an increasing need for thin films with good electrical and mechanical film qualities and relatively low impurity levels. In particular, there is a need to reduce halogen impurities in films deposited by vapor deposition processes using reactants comprising halogens. Thin films can be deposited by a vapor deposition process, such as an atomic layer deposition (“ALD”)-type process, which allows deposition at relatively lower temperatures. However, lower processing temperatures used in an ALD-type process can sometimes lead to degraded film qualities, including degraded electrical and mechanical properties. Without being bound by any one theory, such degraded film qualities may be caused by lower thermal budget associated with certain integration steps in the ALD-type process at relatively lower processing temperatures. In addition, lower processing temperatures may retard crystallization such that the roughness of the film may be increased, and the film quality may be degraded.

Typically, to improve the film qualities, reactants with higher reactivity may be used in the deposition process. However, reactants with higher reactivity are typically more toxic, which may cause more safety hazards. Alternatively, a plasma is used to achieve the higher reactivity of the reactant, such as in a Plasma Enhanced Atomic Layer Deposition (PEALD) process. However, plasma processing can cause damages to the underlying substrate or device. Plasma processing may also incur additional cost and complexity of adding remote or direct plasma systems.

### SUMMARY OF THE INVENTION

The present application relates to vapor deposition processes for improving the qualities of thin films deposited on a hydrogen-terminated surface of a substrate in a reaction space. As discussed in detail below, a growth inhibitor may be included in the deposition process. A growth inhibitor may be a non-consumable agent that is not incorporated into the deposited film to an appreciable extent during the deposition process and helps improve the properties of the deposited film. The growth inhibitor may, for example, be physisorbed to the reactive surface sites on a hydrogen-terminated surface in a vapor deposition process, such as an ALD process, which may effectively block the reactions between those reactive sites and one or more of the reactants, leading to improved film qualities without incorporating the growth inhibitor in the growing film. In some embodiments, the processes may comprise a plurality of deposition cycles in which the substrate is contacted with a first vapor phase reactant and a second vapor phase reactant, such as a first metal precursor and a second nitrogen precursor. In one or more deposition cycles, the substrate may be contacted with a vapor phase growth inhibitor. In some embodiments, the substrate is contacted with the vapor phase growth inhibitor in each deposition cycle. In some embodiments, the substrate is contacted with the vapor phase growth inhibitor intermittently during the deposition process.

In some embodiments, the hydrogen-terminated surface may comprise an —OH or —NH terminated surface, or a metallic surface. In some embodiments, the process may have a deposition temperature of about 200 to about 500° C. In some embodiments, the process may have a deposition temperature of about 300 to about 480° C. In some embodiments, the growth inhibitor may be introduced into the reaction chamber from an external source, for example in one or more pulses during the deposition process.

In some embodiments, the growth inhibitor may comprise a halide, such as a hydrogen halide. In some embodiments the growth inhibitor is HCl. In some embodiments, the growth inhibitor may comprise an organic growth inhibitor, such as acetylacetone (H(acac)), Hexafluoroacetylacetone (H(hfac)), or methylamine.

In some embodiments, at least one of the deposition cycles may further comprise removing excess first vapor phase reactant and reaction byproducts from the reaction space. In some embodiments, at least one of the deposition cycles may further comprise removing excess second vapor phase reactant and reaction byproducts from the reaction space. In some embodiments, at least one of the deposition cycles may further comprise removing excess growth inhibitor and reaction byproducts from the reaction space. In some embodiments the deposition process may be an atomic layer deposition (ALD) process or a chemical vapor deposition (CVD) process. In some embodiments, the deposition process may comprise a cyclic CVD process.

In some embodiments, the thin film that is deposited may comprise a metal nitride. For example, the thin film may be a titanium nitride film, hafnium nitride film, boron nitride film, aluminum nitride film, silicon nitride film, gallium nitride film, niobium nitride film, molybdenum nitride film, indium nitride film, tantalum nitride film, or a tungsten nitride film. In some embodiments, the thin film is a titanium nitride film.

In some embodiments, the first vapor phase reactant may comprise a metal halide precursor. In some embodiments, the metal halide precursor may comprise a metal chloride precursor. In some embodiments, the metal chloride precursor may comprise at least one of titanium tetrachloride (TiCl₄), hafnium tetrachloride (HfCl₄), boron trichloride (BCl₃), aluminum trichloride (AlCl₃), silicon tetrachloride (SiCl₄), disilicon hexachloride (Si₂Cl₆), trisilicon octochloride (Si₃Cl₈), dichlorosilane (SiH₂Cl₂), NiCl₂(TMPDA), gallium monochloride (GaCl), gallium trichloride (GaCl₃), niobium pentachloride (NbCl₅), molybdenum tetrachloride (MoCl₄), molybdenum pentachloride (MoCl₅), molybdenum (V) trichloride oxide (MoOCl₃), molybdenum (VI) tetrachloride oxide (MoOCl₄), molybdenum (IV) dichloride dioxide (MoO₂Cl₂), indium trichloride (InCl₃), tantalum pentachloride (TaCl₅), or tungsten hexachloride (WCl₆).

In some embodiments, the first vapor phase reactant may comprise a metalorganic precursor. In some embodiments, the metalorganic precursor may be selected from the group comprising: tetrakisdimethylamino titanium (TDMAT), tetrakisdiethylamino titanium (TDEAT), pentamethylcyclopentadienyltrimethoxy titanium (CpMe₅Ti(OMe)₃), titanium methoxide (Ti(OMe)₄), titanium ethoxide (Ti(OEt)₄), titanium isopropoxide (Ti(OPr)₄), or titanium butoxide (Ti(OBu)₄).

In some embodiments, the second vapor phase reactant may comprise a nitrogen precursor. For example, in some embodiments the second vapor phase reactant may comprise at least one of molecular nitrogen (N₂), ammonia (NH₃), hydrazine (N₂H₄), a hydrazine derivative, or a nitrogen-based plasma.

In another aspect of this application, an atomic layer deposition (ALD) process for depositing a TiN thin film with an improved film quality on a hydrogen-terminated surface of a substrate in a reaction space is provided. The process may comprise a plurality of cycles comprising alternately contacting the substrate with a first vapor phase titanium reactant and a second vapor phase nitrogen reactant. In one or more deposition cycles, the substrate may be contacted with a growth inhibitor, such as a hydrogen halide. In some embodiments, the substrate is contacted with the growth inhibitor in each deposition cycle. In some embodiments, the substrate is contacted with the growth inhibitor intermittently during the deposition process.

In some embodiments, the first vapor phase reactant may comprise TiCl₄. In some embodiments, the second vapor phase reactant may comprise NH₃. In some embodiments, the growth inhibitor may comprise HCl.

In another aspect of this application, an atomic layer deposition (ALD) process for depositing a TiN thin film with an improved film quality on a hydrogen-terminated surface of a substrate in a reaction space is provided. The process may comprise a plurality of cycles comprising alternately contacting the substrate with a first vapor phase titanium reactant and a second vapor phase nitrogen reactant. In one or more deposition cycles, the substrate may be contacted with a growth inhibitor, such as an organic growth inhibitor. In some embodiments, the substrate is contacted with the growth inhibitor in each deposition cycle. In some embodiments, the substrate is contacted with the growth inhibitor intermittently during the deposition process.

In some embodiments, the first vapor phase reactant may comprise TDMAT. In some embodiments, the second vapor phase reactant may comprise NH₃. In some embodiments, the organic growth inhibitor comprises acetylacetone (H(acac)), Hexafluoroacetylacetone (H(hfac)), or methylamine.

### BRIEF DESCRIPTION OF THE DRAWINGS

The appended drawings are meant to illustrate and not to limit various embodiments, and wherein:

FIGS. 1A-1B are schematic representations of reactions on the surface of a substrate with and without a growth inhibitor in accordance with some embodiments of the present disclosure;

FIG. 2 illustrates an exemplary apparatus in accordance with some embodiments of the present disclosure;

FIG. 3 is a non-limiting flow chart generally illustrating a vapor deposition process in accordance with some embodiments of the present disclosure; and

FIGS. 4A-4C are exemplary experimental data illustrating the improvement of film qualities with the growth inhibitor in accordance with some embodiments of the present disclosure.

### DETAILED DESCRIPTION

Deposition of high-quality thin films is important in semiconductor fabrication processes. Thin films, such as metal nitride films, metal oxide films, metal carbide films, or metal silicide films, can be used in a wide variety of contexts, including as barrier, capping, and work function layers in semiconductor devices, such as FinFETS or gate-all-around (GAA) FETS. In some aspects, methods of depositing thin films, such as metal nitride films, metal carbide films, metal oxide films, or metal silicide films, by vapor deposition are provided. In another aspect, the thin films may be used in a gap-fill process to fill a feature in a patterned semiconductor substrate. For example, in some embodiments, a metal nitride can serve as a conductive barrier within an opening in a dielectric layer. In some aspects, the use of a growth inhibitor in the disclosed methods improves the qualities of thin films deposited by vapor deposition processes. A growth inhibitor may be a non-consumable agent that is not incorporated into the deposited film to an appreciable extent during the deposition process and helps improve the properties of the deposited film. Film qualities, such as resistivity, density, and concentration of impurities, may be improved relative to films that are deposited without the use of a growth inhibitor as disclosed. [0022] Thin films can be deposited on a substrate by a vapor deposition process, such as an atomic layer deposition (“ALD”)-type process or a chemical vapor deposition (CVD)-type process.

In some embodiments, the vapor deposition process is an ALD-type process. In an ALD-type deposition process, vapor phase reactants are separated from each other in the reaction chamber, for example, by removing excess reactants and/or reactant by-products from the reaction chamber between reactant pulses in one or more deposition cycles. This may be accomplished with an evacuation step and/or with a purge step. In some embodiments, the substrate is contacted with a purge gas, such as an inactive gas. For example, the substrate may be contacted with a purge gas between reactant pulses to remove excess reactant and reaction by-products from the reaction space containing the substrate.

ALD-type processes have many advantages, including high conformality at relatively low temperatures and fine control of film composition. ALD-type processes are based on controlled, self-limiting surface reactions of vapor phase reactants. In a time-divided ALD reactor, gas phase reactions are avoided by feeding the precursors alternately and sequentially into the reaction chamber. Vapor phase reactants are separated from each other in the reaction chamber, for example, by removing excess reactants and reactant by-products, if any, from the reaction chamber between reactant pulses or by moving the substrate to remove reactant gases from the vicinity of the substrate surface. Removal of the excess reactants and/or reactant by-products can be done by purging and/or lowering pressure between reactant pulses.

Advantageously, the methods disclosed herein can improve the properties of the films deposited in an ALD-type process without using a more reactive reactant or using plasma under a relatively low temperature range. However, in some embodiments, the methods may be carried out using a highly reactive reactant and/or with a plasma reactant.

As discussed in more detail below, in some embodiments, a thin film is deposited on a substrate by a vapor deposition process comprising a plurality of deposition cycles in which the substrate is contacted with a first vapor phase reactant and a second vapor phase reactant. The process additionally comprises contacting the substrate with one or more growth inhibitors during at least one deposition cycle. In some embodiments, the substrate is alternately and sequentially contacted with the first reactant and second reactant. The growth inhibitor may be provided in a separate pulse in one or more deposition cycles or may be provided in a constant flow throughout a deposition cycle or throughout the entire deposition process. In some embodiments, the growth inhibitor may be provided with one of the first or second reactants. In some embodiments, the growth inhibitor is provided with a first metal reactant, such as a metal halide reactant.

In some embodiments, the vapor deposition process may comprise a hybrid ALD/CVD process, or a cyclic CVD process. For example, in some embodiments, the growth rate of a particular ALD process may be low compared with a CVD process. One approach to increase the growth rate may be that of operating at a higher deposition temperature than that typically employed in an ALD process, resulting in some gas phase reactions and/or decomposition of reactants, but still taking advantage of the sequential introduction of reactants. Although described primarily in the context of ALD-type processes, in some embodiments, a growth inhibitor may be utilized in a sequential or pulsed CVD process or a hybrid ALD/CVD process.

In some embodiments, an ALD-type process is modified to use overlapping or partially overlapping pulses of reactants. In some embodiments, an ALD process is modified to use extremely short purge or removal times, such as below 0.1 s (depending on the reactor). In some embodiments, an ALD process is modified to use extremely long or continuous pulse times. For example, in some embodiments, an ALD process is modified to use no purge or removal at all after at least one reactant pulse. In some embodiments, no purge is used after a metal precursor pulse. In some embodiments, no purge is used after a nitrogen precursor pulse.

Deposition cycles comprising CVD-type processes typically involve gas phase reactions between two or more reactants. The reactants can be provided simultaneously to the reaction space or substrate, or in partially or completely separated pulses. The substrate and/or reaction space can be heated to promote the reaction between the gaseous reactants. In some embodiments, cyclic CVD type processes can be used with multiple deposition cycles to deposit a thin film having a desired thickness. In cyclic CVD-type processes, the reactants may be provided to the reaction chamber in pulses that do not overlap, or that partially or completely overlap. In some embodiments, a cyclic CVD process may comprise the introduction of two or more reactants into the reaction chamber, wherein there may be a time period of overlap between the two or more reactants in the reaction chamber. For example, a cyclic CVD process may comprise the continuous flow of a one reactant and the periodic pulsing of a second reactant into the reaction chamber. A growth inhibitor may be provided in one or more pulses at intervals in the CVD process or may be provided continuously during the CVD process.

In some embodiments, the vapor deposition process comprises contacting the substrate with a first reactant and a second reactant. A growth inhibitor is provided at one or more points in the deposition process. In some embodiments, the growth inhibitor may be provided continuously for the entire deposition process or for a portion of the deposition process.

In some embodiments, the vapor deposition process comprises a plurality of deposition cycles in which the substrate is sequentially contacted with a first reactant and a second reactant. In some embodiments, the vapor deposition process comprises a plurality of deposition cycles in which the substrate is alternately and sequentially contacted with a first reactant and a second reactant. The growth inhibitor may be provided in one or more of the deposition cycles. In some embodiments, the growth inhibitor is provided separately from the other reactants. In some embodiments, the growth inhibitor is provided simultaneously with one or more of the other reactants. In some embodiments, the growth inhibitor is provided continuously during one or more deposition cycles.

In some embodiments, the vapor deposition process is an ALD process comprising a plurality of deposition cycles. In some embodiments, at least one ALD deposition cycle may comprise contacting the substrate with the first and second reactant separately. In some embodiments, the excess reactants and/or reaction byproducts, if any, may be removed from the substrate after the contacting the substrate with the first and/or second reactant. In some embodiments, the deposition cycle may be repeated until a film of desired thickness or other desired property is formed. A growth inhibitor may be provided in one or more of the deposition cycles. In some embodiments, a growth inhibitor is provided in each deposition cycle. In some embodiments, a growth inhibitor is provided in a plurality of deposition cycles. The growth inhibitor may be separately provided in one or more pulses. In some embodiments, the growth inhibitor is provided to the reaction space in a pulse and subsequently removed from the reaction space prior to contacting the substrate with another reactant. In some embodiments, the excess growth inhibitor and/or reaction byproducts, if any, may be removed from the substrate after the contacting the substrate with the growth inhibitor. In some embodiments, the growth inhibitor is provided simultaneously with one or more of the other reactants. In some embodiments, the growth inhibitor is provided continuously throughout one or more deposition cycles or throughout the entire deposition process.

In some embodiments, the surface of the substrate is hydrogen-terminated. In some embodiments, the surface may comprise —OH or —NH terminations. In some embodiments, the hydrogen-terminated surface is a metal or metallic surface.

In some embodiments, the substrate is pretreated before deposition to provide a hydrogen-terminated surface. In some embodiments, a surface treatment may be provided at one or more points in the deposition process to provide a hydrogen-terminated surface. In some embodiments, a separate surface treatment is not necessary.

In some embodiments, the thin film is deposited on a three-dimensional structure in a patterned substrate, such as a trench, hole or via. In some embodiments the structures have high aspect ratios (e.g., aspect ratios of about 6 or higher) or complex morphology. For example, a growth inhibitor may be used in a gap fill process as described in U.S. patent application Ser. No. 17/073,544, which is incorporated by reference herein in its entirety. In some embodiments, the surface on which the thin film is deposited is a planar or substantially planar surface.

In some embodiments, the growth inhibitor may comprise a vapor phase halide. In some embodiments, the growth inhibitor may comprise a hydrogen halide. In some embodiments, the growth inhibitor may comprise HCl, HBr, or HI. In some embodiments, the growth inhibitor is HCl. In some embodiments, the growth inhibitor may comprise an organic molecule. In some embodiments, the growth inhibitor may comprise acetylacetone (H(acac)), Hexafluoroacetylacetone (H(hfac)), or methylamine. In some embodiments, a growth inhibitor is not consumed during the deposition process. In some embodiments, the growth inhibitor is not incorporated into the deposited film during the deposition process. In some embodiments, the growth inhibitor improves one or more properties of the deposited film relative to a film deposited by a corresponding process that does not utilize the growth inhibitor.

In some embodiments, the growth inhibitor may be selected to be the same as a byproduct of a surface reaction that takes place during the deposition process. Thus, additional growth inhibitor may be generated during the deposition process itself.

In some embodiments, the growth inhibitor is provided from a source container located outside of and in fluid communication with the reaction chamber. The growth inhibitor may be provided to the reaction chamber in one or more pulses. In some embodiments the growth inhibitor may be provided with the aid of a carrier gas, such as an inert gas. In some embodiments, a pulse of growth inhibitor may be from about 0.1 s to about 1 minute in length, or from about 0.1 to 10 s, or from about 0.1 to 1 s, or about 0.5 s. In some embodiments, the length of pulse of growth inhibitor may be selected based on the concentration of growth inhibitor. In some embodiments, the length of the pulse of growth inhibitor can be longer if the concentration of the growth inhibitor is lower and can be shorter if the concentration of the growth inhibitor is higher. In some embodiments, more than one pulse of growth inhibitor is provided in a deposition cycle.

As mentioned above, in some embodiments, the growth inhibitor may be supplied throughout the deposition process. In some embodiments, the growth inhibitor may be supplied as a constant flow throughout the deposition process. In some embodiments, the growth inhibitor may be supplied periodically during the deposition process. In some embodiments, the growth inhibitor may be supplied once, twice, three or more times during one deposition cycle. In some embodiments, the growth inhibitor may be supplied in some of the deposition cycles. In some embodiments, the growth inhibitor may be supplied separately from other reactants or purging gas. In some embodiments, the growth inhibitor may be supplied simultaneously with another reactant and/or with purging gas.

In some embodiments, a deposition cycle of a cyclic deposition process for depositing a metal-containing thin film may comprise three or more distinct deposition steps or stages. In a first stage of the unit deposition cycle (“the metal stage”), the substrate surface on which deposition is desired may be contacted with a first vapor phase metal precursor, such as a metal halide precursor or metalorganic precursor, which chemisorbs on to the surface of the substrate. In a second stage of the deposition, the substrate surface on which deposition is desired may be contacted with a second vapor phase reactant that reacts with the adsorbed species of the first reactant to form the desired material. In some embodiments, the second vapor phase reactant may comprise one of a nitrogen precursor, an oxygen precursor, a silicon precursor or a sulfur precursor. In some embodiments, the second vapor phase reactant is a nitrogen reactant, and a metal nitride film is formed. In a third stage of the deposition (“the inhibitor phase”), the substrate surface on which deposition is desired may be contacted with a vapor phase halide growth inhibitor, such as, hydrochloric acid (HCl) vapor. Although labelled the first, second and third stages, the stages may be provided in any order. In addition, the growth inhibitor may be provided in one or more of the first and second phases, rather than in a separate phase. The deposition cycle is repeated to deposit a film of the desired thickness. Additional phases may be added in which the substrate is contacted with additional precursors, for example to form ternary or more complex materials.

Without being bound by any one theory, it is believed that a growth inhibitor may be primarily physisorbed to the reactive surface sites on a hydrogen terminated surface in a vapor deposition process, such as an ALD process, which may effectively block the reactions between the reactive sites and one or more of the reactants. It is believed that the growth inhibitor may be loosely physisorbed to the active sites on a hydrogen-terminated surface and that loosely absorbed growth inhibitor will not be incorporated into the deposited film but leaves available surface hydrogen which may react with excess ligands from the reactants. As the excess ligands from the reactants lead to impurities to the deposited film, the impurity level of the deposited thin film can be lowered at a given processing temperature by the use of the growth inhibitor, as the ligands from the reactants may react with the surface hydrogens. In some embodiments, the impurities may comprise halogen. In some embodiments, the impurities may comprise Cl, Br, and/or I.

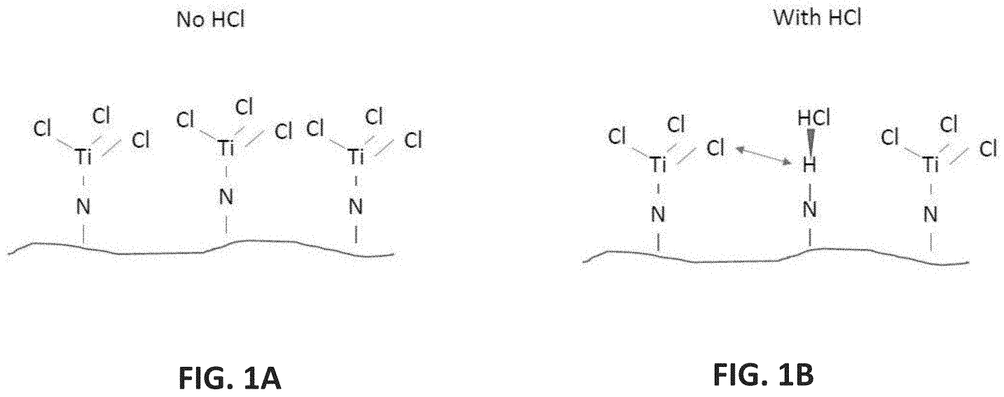

FIGS. 1A-1B schematically illustrates a possible mechanism of the role of growth inhibitors in the growth of a film using a metal halide reactant and HCl as a growth inhibitor. As shown in FIG. 1A, without the addition of growth inhibitor such as HCl, a reactant such as TiCl4 reacts with all of the available binding sites on the substrate surface. A subsequent reactant may not remove all of the Cl ligands. As a result, the resulting thin film may incorporate a relatively high level of impurities, such as Cl. With the addition of growth inhibitor, as shown in FIG. 1B, the growth inhibitor, such as HCl, may be physisorbed to some of the active sites on the surface and block the absorption of TiCl₄ precursor to those active sites. HCl may be formed from a reaction between the excess Cl in the chemisorbed precursor and the surface hydrogen and be removed from the substrate instead of being incorporated into the deposited film. In some embodiments, a growth inhibitor may comprise one or more organic molecules, such as acetylacetone (H(acac)), Hexafluoroacetylacetone (H(hfac)), or methylamine.

In some embodiments, the first vapor phase reactant is a metal precursor. In some embodiments, the metal precursor may be a metal halide precursor. In some embodiments, a metal halide precursor may comprise at least one metal element and at least a halide. In some embodiments, the metal halide precursor may comprise a metal chloride precursor, a metal iodide precursor, or a metal bromide precursor. In some embodiments, the a metal chloride precursor may comprise titanium tetrachloride (TiCl₄), hafnium tetrachloride (HfCl₄), boron trichloride (BCl₃), aluminum trichloride (AlCl₃), silicon tetrachloride (SiCl₄), disilicon hexachloride (Si₂Cl₆), trisilicon octochloride (Si₃Cl₈), dichlorosilane (SiH₂Cl₂), NiCl₂(TMPDA), gallium monochloride (GaCl), gallium trichloride (GaCl₃), niobium pentachloride (NbCl₅), molybdenum tetrachloride (MoCl₄), molybdenum pentachloride (MoCl₅), molybdenum (V) trichloride oxide (MoOCl₃), molybdenum (VI) tetrachloride oxide (MoOCl₄), molybdenum (IV) dichloride dioxide (MoO₂Cl₂), indium trichloride (InCl₃), tantalum pentachloride (TaCl₅), or tungsten hexachloride (WCl₆).

In some embodiments, the metal halide precursor may comprise a metal iodide precursor, such as, titanium tetraiodide (TiI₄), for example. In some embodiments, the metal halide precursor may comprise a metal bromide, such as, titanium tetrabromide.

In some embodiments, the metal precursor may comprise an organic precursor, such as a metalorganic precursor, for example. In some embodiments, the metalorganic precursor may be tetrakisdimethylamino titanium (TDMAT), tetrakisdiethylamino titanium (TDEAT), pentamethylcyclopentadienyltrimethoxy titanium (CpMe₅Ti(OMe)₃), titanium methoxide (Ti(OMe)₄), titanium ethoxide (Ti(OEt)₄), titanium isopropoxide (Ti(OPr)₄), or titanium butoxide (Ti(OBu)₄).

In some embodiments, the second vapor phase reactant may comprise one or more elements to be incorporated in the film. For example, in some embodiments, the second reactant may comprise a nitrogen precursor, an oxygen precursor, a carbon precursor or a sulfur precursor. In some embodiments, the deposited thin film may comprise a metal nitride and the second vapor phase reactant may comprise nitrogen precursor. In some embodiments, the deposited thin film may comprise a metal oxide and the second vapor phase reactant may comprise oxygen precursor. In some embodiments, the thin film may comprise a metal carbide and the second vapor phase reactant may comprise a carbon precursor.

In some embodiments, the thin film may comprise metal nitride. In some embodiments, the first vapor phase reactant may comprise a metal precursor and the second vapor phase reactant may comprise a nitrogen precursor.

In some embodiments, the thin film may comprise metal oxide. In some embodiments, the first vapor phase reactant may comprise a metal precursor and the second vapor phase reactant may comprise an oxygen precursor.

In some embodiments, the thin film may comprise metal carbide. In some embodiments, the first vapor phase reactant may comprise a metal precursor and the second vapor phase reactant may comprise an organic precursor.

In some embodiments, the thin film may comprise metal silicide. In some embodiments, the first vapor phase reactant may comprise a metal precursor and the second vapor phase reactant may comprise a silicon precursor.

In some embodiments, the thin film may comprise metal sulfide. In some embodiments, the first vapor phase reactant may comprise a metal precursor and the second vapor phase reactant may comprise sulfur precursor.

In some embodiments, the nitrogen precursor may comprise, for example, molecular nitrogen (N₂), ammonia (NH₃), hydrazine (N₂H₄), a hydrazine derivative, or a nitrogen-based plasma. In some embodiments, the hydrazine derivative may comprise an alkyl-hydrazine including at least one of: tertbutylhydrazine (C₄H₉N₂H₃), methylhydrazine (CH₃NHNH₂), or dimethylhydrazine ((CH₃)₂N₂H₂).

In some embodiments, the oxygen precursor may comprise, for example, at least one of: water (H₂O), hydrogen peroxide (H₂O₂), ozone (O₃), sulfur trioxide (SO₃), or oxides of nitrogen, such as, for example, nitrogen monoxide (NO), nitrous oxide (N₂O), or nitrogen dioxide (NO₂). In some embodiments of the disclosure, the oxygen precursor may comprise an organic alcohol, such as, for example, isopropyl alcohol.

In some embodiments, the silicon precursor may comprise, for example at least one of: silane (SiH₄), disilane (Si₂H₆), trisilane (Si₃H₈), tetrasilane (Si₄H₁₀), isopentasilane (Si₅H₁₂), or neopentasilane (Si₅H₁₂). In some embodiments, the silicon precursor may comprise a C1-C4 alkylsilane.

Reactants may be separated by inert gases, such as argon (Ar) or nitrogen (N₂), to prevent gas-phase reactions between reactants. In some embodiments, however, the substrate may be moved to separately contact a first vapor phase reactant, a second vapor phase reactant, and a growth inhibitor. Because the reactions self-saturate, strict temperature control of the substrates and precise dosage control of the precursors may not be required. However, the substrate temperature is preferably such that an incident gas species does not condense into monolayers nor decompose on the surface. Surplus reactant and vapor phase growth inhibitor may be removed from the substrate surface by employing a purge cycle, such as, by introducing an inert purge gas into the reaction chamber and exhausting the reaction chamber with the aid of a vacuum pump in fluid communication with the reaction chamber, for example.

The substrate may comprise one or more materials and material surfaces including, but not limited to, semiconductor materials, dielectric materials, and metallic materials.

In some embodiments, the substrate may include semiconductor materials, such as, but not limited to, silicon (Si), germanium (Ge), germanium tin (GeSn), silicon germanium (SiGe), silicon germanium tin (SiGeSn), silicon carbide (SiC), or a group III-V semiconductor materials.

In some embodiments, the substrate may include metallic materials, such as, but not limited to, pure metals, metal nitrides, metal carbides, metal borides, and mixtures thereof.

In some embodiments, the substrate may include dielectric materials, such as, but not limited to, silicon containing dielectric materials and metal oxide dielectric materials. In some embodiments, the substrate may comprise one or more dielectric surfaces comprising a silicon containing dielectric material such as, but not limited to, silicon dioxide (SiO₂), silicon sub-oxides, silicon nitride (Si₃N₄), silicon oxynitride (SiON), silicon oxycarbide (SiOC), silicon oxycarbide nitride (SiOCN), silicon carbon nitride (SiCN). In some embodiments, the substrate may comprise one or more dielectric surfaces comprising a metal oxide such as, but not limited to, aluminum oxide (Al₂O₃), hafnium oxide (HfO₂), tantalum oxide (Ta₂O₅), zirconium oxide (ZrO₂), titanium oxide (TiO₂), hafnium silicate (HfSiOₓ), and lanthanum oxide (La₂O₃).

In some embodiments of the disclosure, the substrate may comprise an engineered substrate wherein a surface semiconductor layer is disposed over a bulk support with an intervening buried oxide (BOX) disposed there between.

Patterned substrates may comprise substrates that may include semiconductor device structures formed into or onto a surface of the substrate, for example, a patterned substrate may comprise partially fabricated semiconductor device structures, such as, for example, transistors and/or memory elements. In some embodiments, the substrate may contain monocrystalline surfaces and/or one or more secondary surfaces that may comprise a non-monocrystalline surface, such as a polycrystalline surface and/or an amorphous surface. Monocrystalline surfaces may comprise, for example, one or more of silicon (Si), silicon germanium (SiGe), germanium tin (GeSn), or germanium (Ge). Polycrystalline or amorphous surfaces may include dielectric materials, such as oxides, oxynitrides, oxycarbides, oxycarbide nitrides, nitrides, or mixtures thereof.

In some embodiments, the substrate may be heated to a deposition temperature (i.e., substrate temperature) of less than about 600° C., or less than about 500° C., or less than about 400° C., or less than about 300° C., or even less than about 200° C. In some embodiments, the substrate may be heated to a deposition temperature between about 200° C. to about 600° C., or between about 200° C. to about 500° C., or between about 300° C. to about 480° C., or between about 400° C. to about 450° C.

In some embodiments, the reaction chamber pressure may be less than about 300 Torr, or less than about 200 Torr, or less than about 100 Torr, or less than about 50 Torr, or less than about 25 Torr, or less than about 10 Torr, or less than about 5 Torr, or less than about 3 Torr, or even less than about 1 Torr. In some embodiments, the reaction chamber pressure may be between about 1 Torr and about 300 Torr, or between about 1 Torr and about 10 Torr, or between about 1 Torr and about 5 Torr, or between about 1 Torr and about 3 Torr. In some embodiments, the pressure may be different for some of the deposition cycles.

Reactors and associated reaction chambers capable of the cyclic deposition processes of the current disclosure may include atomic layer deposition (ALD) reactors and appropriately configured ALD reaction chambers, as well as chemical vapor deposition (CVD) reactors and appropriately configured CVD reaction chambers constructed and arranged to provide the precursors. According to some embodiments, a showerhead reactor may be used. According to some embodiments, cross-flow, batch, minibatch, or spatial ALD reactors may be used.

In some embodiments of the disclosure, a batch reactor may be used. In some embodiments, a vertical batch reactor may be used. In other embodiments, a batch reactor comprises a minibatch reactor configured to accommodate 10 or fewer wafers, 8 or fewer wafers, 6 or fewer wafers, 4 or fewer wafers, or 2 or fewer wafers.

In some embodiments, the deposition processes of the current disclosure may be performed in a single stand-alone reactor which may be equipped with a load-lock.

In some embodiments, the deposition apparatus may include three or more reactant source vessels fluidly connected to a reaction chamber. For example, the three or more reactant source vessels may comprise: a first vapor phase reactant source, such as a metal halide reactant source, a second vapor phase reactant source, such as a nitrogen reactant source, and a third growth inhibitor reactant source, such as an HCl source. In addition, one or more additional source vessels may be fluidly connected to the reaction chamber, wherein the additional source vessels may contain additional reactants, such as additional precursors that may be used, for example, to deposit ternary or more complex films.

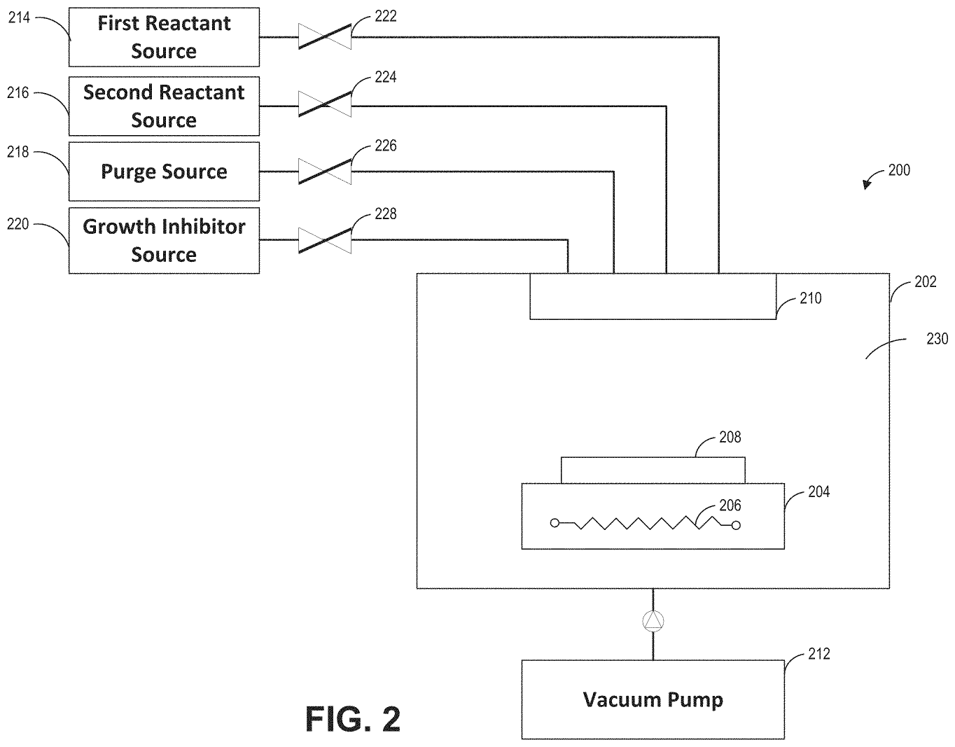

FIG. 2 schematically illustrates an exemplary apparatus in accordance with some embodiments of the present disclosure. As shown in FIG. 2, the apparatus 200 may comprise a reactor 202 which may further comprise a first reaction chamber 230, a susceptor 204 to support a substrate 208 and a showerhead 210 or other reactant vapor distribution system. The susceptor 204 may comprise a heating element 206, which can be used to control the temperature of the substrate 208. The apparatus 200 may also comprise a reactant delivery system which may further comprise a first reactant source vessel 214; a second reactant source vessel 216; a purge gas source vessel 218, and a growth inhibitor source vessel 220. Although illustrated with four source vessels, the configuration can be adjusted depending on the particular deposition process to be implemented. The apparatus 200 may further comprise valves 222, 224, 226, and 228 interposed between the vessels 214, 216, 218, 220 and the reactor 202 to control the flow of the various reactants and purge gas into the reaction chamber 230 where it contacts the substrate 208. The reaction chamber 230 may be a standalone reaction chamber or a part of a cluster tool. Further, the reaction chamber 230 may operate under a vacuum or near atmospheric pressure, and the pressure can be controlled with a vacuum pump 212. The reaction chamber 230 may be configured to be suitable for vapor deposition processes, such as ALD or CVD processes. In some embodiments, the apparatus 200 may comprise a plurality of reaction chambers 230, and the substrate 208 may be transferred among different reaction chambers during the deposition processes. The apparatus may further comprise a controller (not shown), configured to control the provision of reactants and growth inhibitor to the reaction chamber and removal of excess reactants and reaction byproducts, if any, according to a particular process.

In some embodiments, the first reactant source vessel 214 comprises a first metal halide reactant, the second reactant source vessel 216 comprises a second reactant, such as a nitrogen reactant, and the growth inhibitor source vessel 220 comprises a halide growth inhibitor, such as HCl. In some embodiments the controller (not shown) may be configured to provide separated pulses of first reactant, second reactant and growth inhibitor from source vessels 214, 216 and 220 respectively to the reaction chamber 230 as described herein. The reactants may be provided through the showerhead 210 into the reaction chamber 230 where they contact the substrate 208. After the desired amount of time, excess reactant and reaction byproducts can be removed from the reaction chamber 230, for example, with the aid of a purge gas from source vessel 218, and with the action of the vacuum pump 212.

In some embodiments, the impurity level in the deposited film may be significantly reduced with the use of growth inhibitor relative to a film deposited under the same conditions in the absence of the growth inhibitor. In some embodiments, the amount of impurity in a deposited thin film according to some of the embodiments may be reduced by more than about 5%, about 10%, about 15%, about 20%, about 30%, about 50%, or more compared to a thin film deposited under the same conditions without the use of the growth inhibitor. In some embodiments, a thin film is deposited with a metal halide precursor and by using a growth inhibitor as described herein the thin film may have an atomic-% of halide impurities of less than about 5, less than about 4, or less than about 1 atomic-%. In some embodiments a TiN thin film is deposited with a titanium halide precursor such as TiCl₄ and a nitrogen reactant and by using an HCl growth inhibitor as described herein the thin film may have an atomic-% of halide impurities of less than about less than 5, about less than 4, or about less than 1 atomic-%. The atomic-% of impurities in the deposited thin films of the present disclosure may be determined, for example, by Rutherford backscattering spectrometry (RBS), for example.

In some embodiments, the density of the deposited film may be significantly increased with the supply of growth inhibitor at a certain processing temperature relative to a film deposited under the same conditions in the absence of the growth inhibitor. In some embodiments, the density of a deposited thin film according to some of the embodiments may be increased by more than about 3%, about 5%, about 10%, about 15%, about 20%, or more compared to a thin film deposited under the same conditions without the use of the growth inhibitor. Without being bound by any one theory, the density of the deposited film may be increased because there are less impurities in the deposited film with the use of growth inhibitor. In some embodiments, a TiN thin film is deposited with a titanium halide precursor such as TiCl₄ and a nitrogen reactant and by using an HCl growth inhibitor as described herein the thin film may have a density of greater than 4.6 g/cm³. In some embodiments, the growth inhibitor may comprise one or more organic molecules. In some embodiments, the growth inhibitor may comprise acetylacetone (H(acac)), Hexafluoroacetylacetone (H(hfac)), or methylamine.

In some embodiments, the resistivity of the deposited film may be significantly reduced with the supply of growth inhibitor relative to a film deposited under the same conditions in the absence of the growth inhibitor. In some embodiments, the resistivity of a deposited thin film according to some of the embodiments may be reduced by more than about 5%, about 10%, about 15%, about 20%, about 30%, about 50%, or more compared to a thin film deposited under the same conditions without the use of the growth inhibitor.

In some embodiments, the surface roughness may be improved with the supply of growth inhibitor relative to a film deposited under the same conditions in the absence of the growth inhibitor.

In some embodiments, the deposited thin film may be deposited to an average film thickness of between 10 Å and 500 Å. In some embodiments, the deposited thin film comprises a titanium nitride film deposited to an average film thickness of between 10 Å and 500 Å. In some embodiments, the deposited thin film may have a thickness of about 100 Å, about 500 Å, about 1 nm, about 5 nm, about 10 nm, about 15 nm, about 20 nm, or any other desired thickness.

In some embodiments, the deposited thin film may be physically continuous at an average film thickness of less than 10 Å. In some embodiments, the deposited thin film comprises a titanium nitride film which may be physically continuous at an average film thickness of less than 10 Å. In addition, in some embodiment, the deposited thin film may comprise a titanium nitride film with an average film thickness of less than 60 Å and an electrical resistivity of less than 250 μΩ-cm.

In some embodiments, the deposited thin film may comprise ternary film, such as, for example, a ternary metal nitride film, a ternary metal oxide film, a ternary metal carbide film, a ternary metal silicide film, a ternary metal sulfide film, a ternary metal selenide film, a ternary metal phosphide film, a ternary metal boride film, or mixtures and/or laminates thereof. In some embodiments, the ternary thin film may comprise at least of: titanium aluminum nitride (TiAlN), titanium aluminum carbide (TiAlC), titanium niobium nitride (TiNbN), or titanium silicon nitride (TiSiN).

### A. Example Methods for Depositing Thin Films on a Hydrogen Terminated Substrate Surface

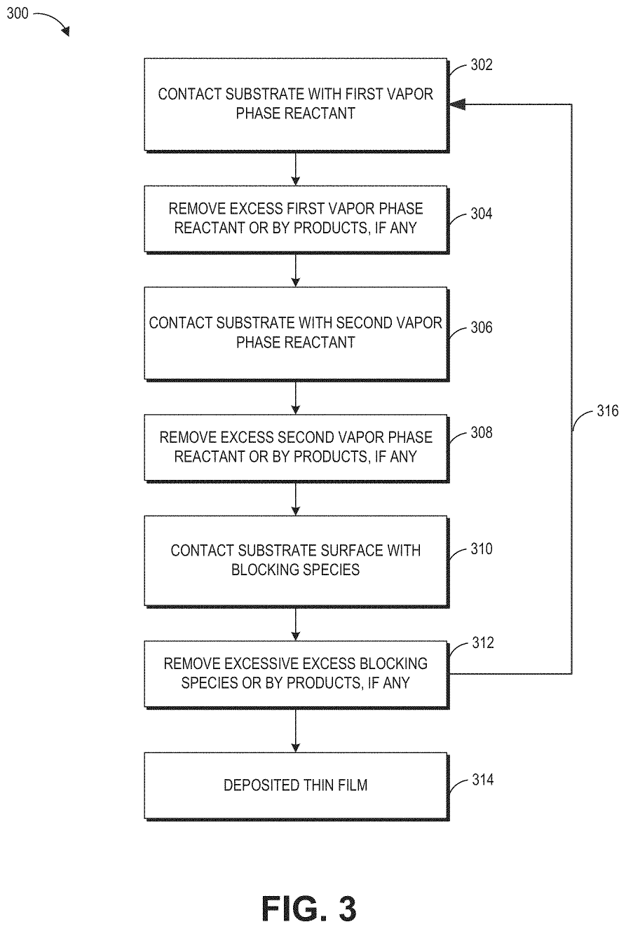

FIG. 3 is a non-limiting exemplary flow chart generally illustrating a vapor deposition process 300, such as an ALD process, including the supply of growth inhibitor during the deposition process in accordance with some embodiments. According to certain embodiments, a thin film with one or more improved qualities, such as less impurities, may be formed on a substrate by vapor deposition process comprising multiple deposition cycles in which a growth inhibitor is provided in one or more deposition cycles relative to a thin film deposited under the same conditions in which a growth inhibitor is not provided in the deposition process.

In some embodiments, a substrate on which a thin film is to be deposited is loaded into a reaction chamber and is heated and maintained at a suitable deposition temperature. In some embodiments, the deposition temperature may be selected to be lower than the precursor thermal decomposition temperature. In some embodiments, the deposition temperature may be selected to be high enough to maintain the vapor phase of the reactants and to provide sufficient activation energy for the desired surface reactions. In some embodiments, the appropriate deposition temperature for a particular process may depend on the surface termination and reactant species involved.

In some embodiments, the substrate may be heated to a deposition temperature (i.e., substrate temperature) of less than about 600° C., or less than about 500° C., or less than about 400° C., or less than about 300° C., or even less than about 200° C. In some embodiments, the substrate may be heated to a deposition temperature between about 200° C. to about 600° C., or between about 300° C. to about 500° C., or between about 300° C. to about 480° C., or between about 400° C. to about 450° C.

Prior to beginning the deposition cycle, the substrate may optionally be treated to provide a hydrogen terminated surface. With reference to FIG. 3, in each of the deposition cycles, in step 302, the substrate is first contacted with a first vapor phase reactant.

In some embodiments, the first vapor phase reactant is metal precursor. In some embodiments, the metal precursor may be a metal halide precursor. In some embodiments, a metal halide precursor may comprise at least one metal element and at least a halide. In some embodiments, the metal halide precursor may comprise a metal chloride precursor, a metal iodide precursor, or a metal bromide precursor. In some embodiments, the a metal chloride precursor may comprise titanium tetrachloride (TiCl₄), hafnium tetrachloride (HfCl₄), boron trichloride (BCl₃), aluminum trichloride (AlCl₃), silicon tetrachloride (SiCl₄), disilicon hexachloride (Si₂Cl₆), trisilicon octochloride (Si₃Cl₈), dichlorosilane (SiH₂Cl₂), NiCl₂(TMPDA), gallium monochloride (GaCl), gallium trichloride (GaCl₃), niobium pentachloride (NbCl₅), molybdenum tetrachloride (MoCl₄), molybdenum pentachloride (MoCl₅), molybdenum (V) trichloride oxide (MoOCl₃), molybdenum (VI) tetrachloride oxide (MoOCl₄), molybdenum (IV) dichloride dioxide (MoO₂Cl₂), indium trichloride (InCl₃), tantalum pentachloride (TaCl₅), or tungsten hexachloride (WCl₆).

In some embodiments, the metal halide precursor may comprise a metal iodide precursor, such as, titanium tetraiodide (TiI₄), for example. In some embodiments, the metal halide precursor may comprise a metal bromide, such as, titanium tetrabromide.

In some embodiments, a TiN film is deposited, and the first vapor phase reactant comprises TiCl₄.

In some embodiments, the metal precursor may comprise an organic precursor, such as, a metalorganic precursor, for example. In some embodiments, the metalorganic precursor may be selected from the group comprising: tetrakisdimethylamino titanium (TDMAT), tetrakisdiethylamino titanium (TDEAT), pentamethylcyclopentadienyltrimethoxy titanium (CpMe₅Ti(OMe)₃), titanium methoxide (Ti(OMe)₄), titanium ethoxide (Ti(OEt)₄), titanium isopropoxide (Ti(OPr)₄), or titanium butoxide (Ti(OBu)₄). In some embodiments, a TiN film is deposited, and the first vapor phase reactant comprises TDMAT.

In some embodiments, contacting the substrate with the first vapor phase reactant may comprise contacting the substrate with the first vapor phase reactant for a time period of between about 0.01 seconds and about 60 seconds, between about 0.05 seconds and about 20 seconds, or between about 0.1 seconds and about 10.0 seconds, or between 0.1 seconds and 5 seconds. In addition, during the contacting of the substrate with the first vapor phase reactant, the flow rate of the first vapor phase reactant may be less than 10,000 sccm, or less than about 8000 sccm, or less than about 6000 sccm, or less than about 4000 sccm, or less than about 2000 sccm, or less than about 1000 sccm, or between about 10 sccm to about 20,000 sccm, or between about 1000 sccm to about 8000 sccm, or even between about 5000 sccm to about 70000 sccm.

Referring back to FIG. 3, in step 304, excess first vapor phase reactant and/or by-products, if any, may be removed from the vicinity of the substrate. In some embodiments, the excess first vapor phase reactant and/or the by-products may be removed by purging the reaction chamber with the aid of a vacuum pump in fluid communication with the reaction chamber, for example, purging with an inert gas. The purge process may comprise a purge cycle, wherein the substrate surface is purged for a time period of less than about 5 seconds, or less than about 3 seconds, or less than about 2 seconds, or even less than about 1 second. In some embodiments, the substrate surface is purged for a time period between about 0.1 seconds and about 5 seconds. In some embodiments, the excess first vapor phase reactant and/or the by-products may be removed by moving the substrate in order to facilitate removal of the reactant and/or reactant byproducts, for example by moving the substrate to a different reaction chamber.

In step 306, the substrate is contacted with a second vapor phase reactant. The second vapor phase reactant may react with adsorbed species of the first reactant on the substrate surface to form the desired material, such as a metal nitride, metal oxide, metal carbide or metal silicide. In some embodiments, the second reactant may comprise a nitrogen precursor, an oxygen precursor, a carbon precursor, or a silicon precursor. In some embodiments, the second reactant is not a plasma reactant.

In some embodiments, the nitrogen precursor may comprise molecular nitrogen (N₂), ammonia (NH₃), hydrazine (N₂H₄), a hydrazine derivative, or a nitrogen-based plasma. In some embodiments, the hydrazine derivative may comprise an alkyl-hydrazine including at least one of: tertbutylhydrazine (C₄H₉N₂H₃), methylhydrazine (CH₃NHNH₂), or dimethylhydrazine ((CH₃)₂N₂H₂).

In some embodiments, the oxygen precursor may comprise at least one of: water (H₂O), hydrogen peroxide (H₂O₂), ozone (O₃), sulfur trioxide (SO₃), or oxides of nitrogen, such as, for example, nitrogen monoxide (NO), nitrous oxide (N₂O), or nitrogen dioxide (NO₂). In some embodiments, of the disclosure, the oxygen precursor may comprise an organic alcohol, such as, for example, isopropyl alcohol.

In some embodiments, the carbon precursor may comprise an organic precursor.

In some embodiments, the silicon precursor may comprise at least one of: silane (SiH₄), disilane (Si₂H₆), trisilane (Si₃H₈), tetrasilane (Si₄H₁₀), isopentasilane (Si₅H₁₂), or neopentasilane (Si₅H₁₂). In some embodiments, the silicon precursor may comprise a C1-C4 alkylsilane.

In some embodiments a TiN film is deposited and the second reactant comprises a nitrogen reactant, such as NH₃.

In some embodiments of the disclosure, contacting the substrate with the second vapor phase reactant may comprise, contacting the substrate with the second vapor phase reactant for a time period of between about 0.01 seconds and about 60 seconds, between about 0.05 seconds and about 20 seconds, or between about 0.1 seconds and about 10.0 seconds, or between 0.1 seconds and about 5 seconds. In addition, during the contacting of the substrate with the second vapor phase reactant, the flow rate of the second vapor phase reactant may be less than about 10,000 sccm, or less than about 8000 sccm, or less than about 6000 sccm, or less than about 4000 sccm, or less than about 2000 sccm, or less than about 1000 sccm, or between about 10 sccm to about 20,000 sccm, or between about 1000 sccm to about 8000 sccm, or even between about 5000 sccm to about 70000 sccm.

Referring back to FIG. 3, in step 308, excess second vapor phase reactant and/or by-products, if any, may be removed from the vicinity of the substrate. In some embodiments, the excess second vapor phase reactant and/or the by-products may be removed by purging the reaction chamber, for example, purging with an inert gas. The purge process may comprise a purge cycle, wherein the substrate surface is purged for a time period of less than about 5 seconds, or less than about 3 seconds, or less than about 2 seconds, or even less than about 1 second. In some embodiments, the substrate surface is purged for a time period between about 0.1 seconds and about 5 seconds. In some embodiments, the excess second vapor phase reactant and/or the by-products may be removed by moving the substrate in order to facilitate removal of the reactant and/or reactant byproducts, for example by moving the substrate to a different reaction chamber.

In step 310, the substrate may be contacted with a pulse of growth inhibitor. In some embodiments, the growth inhibitor comprises a vapor phase reactant. A growth inhibitor may be a non-consumable agent that is not incorporated into the deposited film during the deposition process and helps improve the properties of the deposited film. In some embodiments, the growth inhibitor may comprise one or more organic molecules. In some embodiments, the growth inhibitor may comprise acetylacetone (H(acac)), Hexafluoroacetylacetone (H(hfac)), or methylamine. In some embodiments, the growth inhibitor is a vapor phase halide, such as HCl. In some embodiments, the growth inhibitor is the same as a byproduct of the surface reaction between the first vapor phase reactant and the second vapor phase reactant.

As a non-limiting example, a metal nitride may be deposited where the first vapor phase reactant may comprise a metal halide, such as, titanium tetrachloride (TiCl₄), for example, and the second vapor phase reactant may comprise a nitrogen precursor, such as, ammonia (NH₃), for example. A vapor phase halide, such as a hydrogen halide like HCl may be used as the growth inhibitor.

In some embodiments, TiN may be deposited where the first vapor phase reactant may comprise a titanium halide, such as titanium tetrachloride (TiCl₄), for example, and the second vapor phase reactant may comprise a nitrogen precursor, such as, ammonia (NH₃), for example. HCl may be utilized as the growth inhibitor in one or more deposition cycles.

As another non-limiting example, a metal nitride may be deposited where the first vapor phase reactant may comprise a metalorganic precursor, such as tetrakis(dimethylamino)titanium (TDMAT), and the second vapor phase reactant may comprise a nitrogen precursor, such as ammonia (NH₃). An organic molecule, such as methylamine or H(aca), may be used as a growth inhibitor.

In some embodiments, TiN may be deposited where the first vapor phase reactant may comprise a titanium organic precursor, such as tetrakis(dimethylamino)titanium (TDMAT), and the second vapor phase reactant may comprise a nitrogen precursor, such as ammonia (NH₃). An organic molecule, such as methylamine or H(aca), may be used as a growth inhibitor.

In some embodiments, contacting the substrate with the growth inhibitor may comprise contacting the substrate with the growth inhibitor for a time period of between about 0.01 seconds and about 30 seconds, between about 0.05 seconds and about 10 seconds, or between about 0.1 seconds and about 5 seconds, or between about 0.1 seconds and about 1 seconds, or between 0.1 seconds and 0.8 seconds. In some embodiments, the time period of contacting the substrate with the growth inhibitor may be about 0.1 second, about 0.3 second, about 0.4 second, about 0.7 second, about 0.9 second, about 1 second, about 5 seconds, or any other time period. In some embodiments the growth inhibitor is pulsed into the reaction chamber. In some embodiments the substrate may be moved to a reaction space comprising the growth inhibitor.

In some embodiments, the flow rate of the growth inhibitor may be less than 500 sccm, or less than 250 sccm, or less than 100 sccm, or less than 50 sccm, or between 1 sccm to 500 sccm, or between 25 sccm to 250 sccm, or even between 50 sccm to 100 sccm.

Alternative to step 310, the substrate may be contacted with a constant flow of the growth inhibitor throughout the deposition cycle.

In step 312, excess growth inhibitor and/or by-products, if any, may be removed from the vicinity of the substrate. In some embodiments, the excess growth inhibitor and/or by-products may be removed by purging the reaction chamber, for example, purging with an inert gas. The purge process may comprise a purge cycle, wherein the substrate surface is purged for a time period of less than about 5 seconds, or less than about 3 seconds, or less than about 2 seconds, or even less than about 1 second. In some embodiments, the substrate surface is purged for a time period between about 0.1 seconds and about 5 seconds. In some embodiments, the excess growth inhibitor and/or by-products may be removed by moving the substrate in order to facilitate removal of the reactant and/or byproducts, for example by moving the substrate to a different reaction space or reaction chamber.

The deposition cycle may be repeated 316 until a film of desired thickness is formed.

The pressure of the reaction chamber may be less than about 300 Torr, or less than about 200 Torr, or less than about 100 Torr, or less than about 50 Torr, or less than about 25 Torr, or less than about 10 Torr, or less than about 5 Torr, or less than about 3 Torr, or even less than about 1 Torr. In some embodiments, the reaction chamber pressure may be between about 1 Torr and about 300 Torr, or between about 1 Torr and about 10 Torr, or between 1 Torr and about 5 Torr, or between about 1 Torr and about 3 Torr. In some embodiments, the pressure may be different for some of the deposition cycles.

In some embodiments, the sequence of contacting the substrate with the first vapor phase reactant 302, the second vapor phase reactant 306, and the growth inhibitor 310 may be exchanged. In some embodiments, removing reactant at any of steps 304, 308, and/or 312 may be omitted. In some embodiments, the sequence of steps 302, 306, and 310 may be different in two or more different deposition cycles. In some embodiments, a deposition cycle may start with contacting the substrate with a second vapor phase reactant 306 or contacting the substrate with a growth inhibitor 310.

B. Examples of Deposited Thin Films and their Characteristics

Thin films comprising titanium nitride (TiN) were deposited by ALD process according to some embodiments and described herein. The thin films comprising TiN were deposited on a flat substrate. Titanium tetrachloride was used as the first vapor phase reactant, ammonia (NH₃) was used as the second vapor phase reactant, and hydrogen chloride (HCl) was used as the growth inhibitor to form a TiN thin film with improved properties. Sample thin films comprising TiN were deposited at temperatures of 300° C., 350° C. and 450° C. The sample thin film samples were deposited by a deposition process comprising a plurality of deposition cycles, each cycle comprises contacting the substrate with a first vapor phase reactant comprising TiCl₄, purging, contacting the substrate with a second vapor phase reactant comprising NH₃, purging, contacting the substrate with a growth inhibitor comprising HCl for a period of about 0.5 second, and purging. Each of the deposited thin film had a thickness of more than about 10 nm.

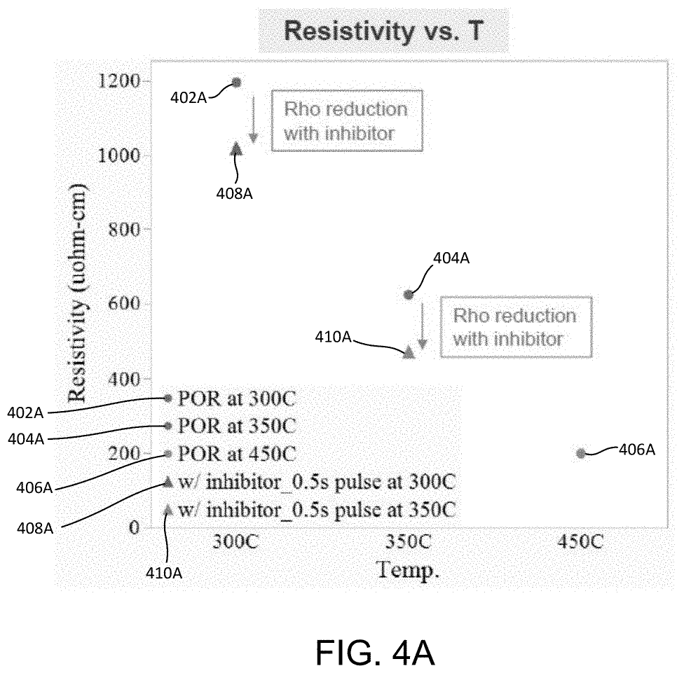

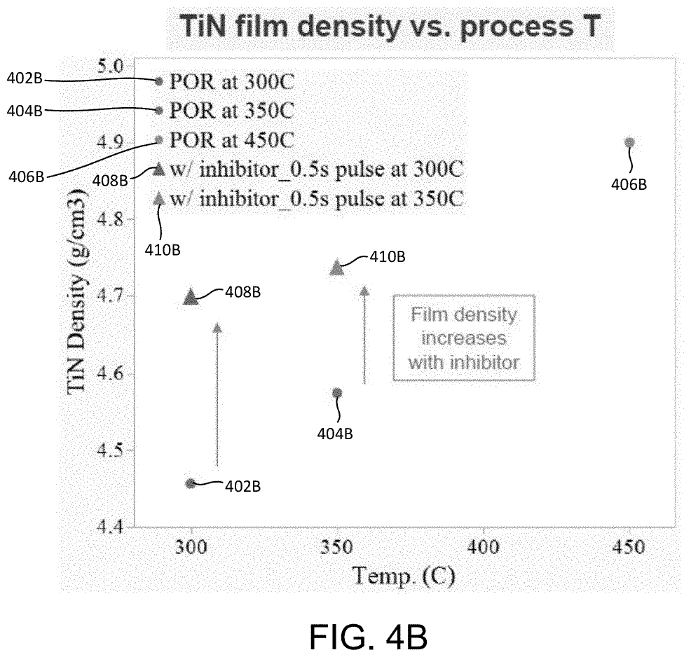

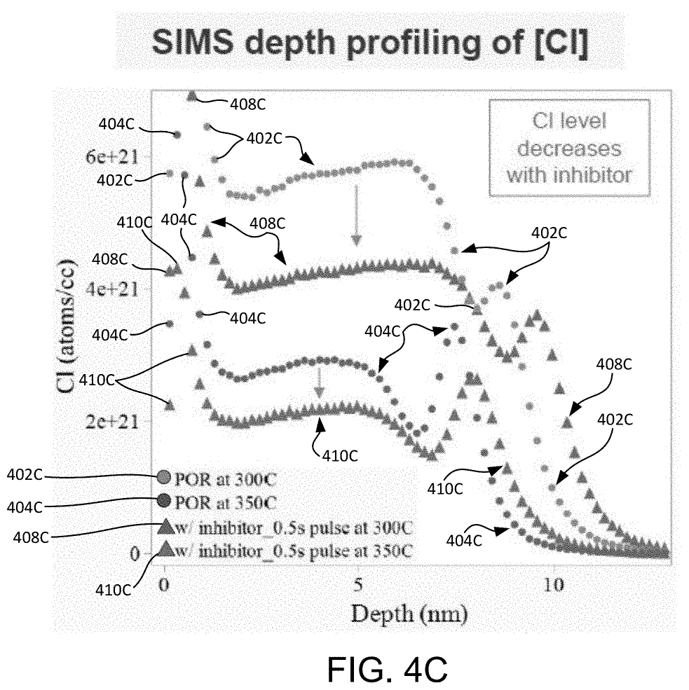

FIG. 4A illustrates exemplary experimental data demonstrating the decrease of the resistivity of the deposited TiN thin film with the addition of growth inhibitor at different temperatures. FIG. 4A clearly demonstrates that the TiN thin film deposited by a process with the addition of growth inhibitor have a lower resistivity and a better electrical conductance compared to the TiN thin films deposited without the addition of growth inhibitor during the deposition process.

FIG. 4B illustrates exemplary experimental data demonstrating the increase of the density of the TiN thin film obtained by a process with the addition of growth inhibitor at different temperatures. FIG. 4B clearly demonstrates that the deposited TiN thin films by the process with the addition of growth inhibitor have a higher density compared to the TiN thin films deposited without the addition of growth inhibitor during the deposition process.

FIG. 4C illustrates exemplary experimental data demonstrating the decrease of the amount of chlorine in the TiN thin film deposited with the addition of growth inhibitor at different temperatures. FIG. 4C clearly demonstrates that the TiN thin films deposited by the process with the addition of growth inhibitor have a lower amount of chlorine impurities compared to the TiN thin films deposited without the addition of growth inhibitor during the deposition process.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combination of the elements described, may become apparent to those skilled in the art from the description. Such modifications and embodiments are also intended to fall within the scope of the appended claims.

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

A number of example materials are given throughout the embodiments of the current disclosure, it should be noted that the chemical formulas given for each of the example materials should not be construed as limiting and that the non-limiting example materials given should not be limited by a given example stoichiometry.

What is claimed is:

1. A vapor deposition process, comprising:
providing a substrate comprising a hydrogen-terminated surface in a reaction chamber; and
depositing a thin film on the substrate by a plurality of deposition cycles comprising:
contacting the substrate with a first vapor phase metal precursor;
contacting the substrate with a second vapor phase reactant; and
contacting the substrate with a vapor phase growth inhibitor,
wherein the growth inhibitor comprises a halide growth inhibitor or an organic growth inhibitor.

2. The vapor deposition process of claim 1, wherein the hydrogen-terminated surface comprises a —OH-terminated, —NH-terminated, or a metallic surface.

3. The vapor deposition process of claim 1, wherein the process is carried out at a deposition temperature of about 200 to about 500° C.

4. The vapor deposition process of claim 1, wherein at least one of the deposition cycles further comprises removing excess first vapor phase metal precursor and reaction byproducts from the reaction space.

5. The vapor deposition process of claim 1, wherein at least one of the deposition cycles further comprises removing excess second vapor phase reactant and reaction byproducts from the reaction space.

6. The vapor deposition process of claim 1, wherein the vapor phase growth inhibitor is contacted with the substrate by pulsing the vapor phase growth inhibitor into the reaction chamber containing the substrate for a period of about 0.1 to about 1 s.

7. The vapor deposition process of claim 1, wherein the substrate is contacted with a vapor phase halide growth inhibitor comprising HCl, HBr, or HI.

8. The vapor deposition process of claim 1, wherein the substrate is contacted with an organic growth inhibitor comprising acetylacetone (H(acac)), hexafluoroacetylacetone (H(hfac)), or methylamine.

9. The vapor deposition process of claim 1, wherein the first vapor phase metal precursor comprises a metal halide precursor or a metalorganic precursor.

10. The vapor deposition process of claim 9, wherein the metal halide precursor comprises at least one of titanium tetrachloride (TiCl₄), hafnium tetrachloride (HfCl₄), boron trichloride (BCl₃), aluminum trichloride (AlCl₃), silicon tetrachloride (SiCl₄), disilicon hexachloride (Si₂Cl₆), trisilicon octochloride (Si₃Cl₈), dichlorosilane (SiH₂Cl₂), NiCl₂(TMPDA), gallium monochloride (GaCl), gallium trichloride (GaCl₃), niobium pentachloride (NbCl₅), molybdenum tetrachloride (MoCl₄), molybdenum pentachloride (MoCl₅), molybdenum (V) trichloride oxide (MoOCl₃), molybdenum (VI) tetrachloride oxide (MoOCl₄), molybdenum (IV) dichloride dioxide (MoO₂Cl₂), indium trichloride (InCl₃), tantalum pentachloride (TaCl₅), or tungsten hexachloride (WCl₆).

11. The vapor deposition process of claim 9, wherein the metalorganic precursor comprises tetrakisdimethylamino titanium (TDMAT), tetrakisdiethylamino titanium (TDEAT), pentamethylcyclopentadienyltrimethoxy titanium (CpMe₅Ti(OMe)₃), titanium methoxide (Ti(OMe)₄), titanium ethoxide (Ti(OEt)₄), titanium isopropoxide (Ti(OPr)₄), or titanium butoxide (Ti(OBu)₄).

12. The vapor deposition process of claim 1, wherein the thin film comprises a metal nitride film.

13. The vapor deposition process of claim 12, wherein the second vapor phase reactant comprises at least one of molecular nitrogen (N₂), ammonia (NH₃), hydrazine (N₂H₄), a hydrazine derivative, or a nitrogen-based plasma.

14. The vapor deposition process of claim 12, wherein the thin film comprises a titanium nitride film.

15. The vapor deposition process of claim 14, wherein the first vapor phase metal precursor comprises TiCl₄ and the vapor phase growth inhibitor comprises HCl.

16. The vapor deposition process of claim 14, wherein the first vapor phase metal precursor comprises TDMAT and the vapor phase growth inhibitor comprises acetylacetone (H(acac)) or methylamine.

17. A process for depositing a titanium nitride (TiN) thin film, comprising:
providing a substrate comprising a hydrogen-terminated surface in a reaction chamber; and
depositing the TiN thin film by an atomic layer deposition (ALD) process comprising a plurality of deposition cycles, at least one of the plurality of deposition cycles comprising:
contacting the substrate with a titanium halide precursor;
contacting the substrate with a nitrogen reactant; and
contacting the substrate with a growth inhibitor comprising HCl.

18. The process of claim 17, wherein the titanium halide precursor comprises TiCl₄.

19. The process of claim 17, wherein the nitrogen reactant comprises NH₃.

20. The process of claim 17, wherein the substrate is alternately and sequentially contacted with the titanium halide precursor, the nitrogen reactant, and the growth inhibitor.
